(19) United States
(12) Patent Application Publication
(10) Pub. No.: US 2025/0212465 A1
(43) Pub. Date: Jun. 26, 2025

(54) THIN FILM TRANSISTOR, MEMORY AND METHOD OF MANUFACTURING THIN FILM TRANSISTOR

(71) Applicants: Beijing Superstring Academy of Memory Technology, Beijing (CN); INSTITUTE OF MICROELECTRONICS, CHINESE ACADEMY OF SCIENCES, Beijing (CN)

(72) Inventors: Gaobo XU, Beijing (CN); Yunjiao BAO, Beijing (CN); Gangping YAN, Beijing (CN); Chuqiao NIU, Beijing (CN); Yanyu YANG, Beijing (CN)

(73) Assignees: Beijing Superstring Academy of Memory Technology, Beijing (CN); INSTITUTE OF MICROELECTRONICS, CHINESE ACADEMY OF SCIENCES, Beijing (CN)

(21) Appl. No.: 18/987,193

(22) Filed: Dec. 19, 2024

(30) Foreign Application Priority Data
Dec. 21, 2023 (CN) 202311775135.0

(51) Int. Cl. H10D 30/67; H10B 12/00; H10D 30/01

(52) U.S. Cl. CPC H10D 30/6757; H10B 12/30; H10D 30/031; H10D 30/6706; H10D 30/6755

(57) ABSTRACT

A thin film transistor, a memory, and a method of manufacturing a thin film transistor are provided, which relate to a field of semiconductor device technology. The thin film transistor includes a substrate; a gate on a surface of the substrate; an insulation layer covering the gate; a source and a drain; a channel between the insulation layer and the source and the drain, wherein the source and the drain are located on a surface of the channel away from the substrate; and an insulation dielectric layer between the source and the drain, wherein the insulation dielectric layer partially overlaps with the channel in a first direction, wherein the substrate, the gate, the insulation layer, the source and the drain, the channel, and the insulation dielectric layer are stacked in the first direction.

### CROSS REFERENCE TO RELATED APPLICATION

This application claims the benefit of priority to Chinese Patent Application No. 202311775135.0, filed on Dec. 21, 2023. The entire contents of this application are hereby incorporated herein by reference.

### TECHNICAL FIELD

The present disclosure relates to a field of a semiconductor device technology, and in particular to a thin film transistor, a memory, and a method of manufacturing a thin film transistor.

### BACKGROUND

Dynamic Random Access Memory (DRAM) is a volatile, capacitor-based, destructive read form of semiconductor memory that currently accounts for more than 50% of the memory market.

DRAM includes memory cells, and the memory cell includes a transistor. When the memory cell is written, the transistor is turned on, and charges are transferred to a capacitor (1) or transferred from a capacitor (0). When the memory cell is read, the charges are extracted and measured.

A thin film transistor (TFT) is a field-effect transistor that includes a channel layer, a gate, and a source and a drain on a supporting but non-conductive substrate. Due to advantages such as low leakage current, low growth temperature and high mobility, the thin film transistor has been widely used in various devices, such as memories.

### SUMMARY

In an aspect, the present disclosure provides a thin film transistor. The thin film transistor includes: a substrate; a gate on a surface of the substrate; an insulation layer covering the gate; a source and a drain; a channel between the insulation layer and the source and the drain, where the source and the drain are located on a surface of the channel away from the substrate; and an insulation dielectric layer between the source and the drain, where the insulation dielectric layer partially overlaps with the channel in a first direction, where the substrate, the gate, the insulation layer, the source and the drain, the channel and the insulation dielectric layer are stacked in the first direction.

In some embodiments of the present disclosure, a gap is provided between the source and the drain, and the insulation dielectric layer includes a first top surface facing the gap; where the channel includes a second top surface facing the source and/or the drain.

In some embodiments of the present disclosure, the first top surface is flush with the second top surface.

In some embodiments of the present disclosure, the first top surface is higher than the second top surface.

In some embodiments of the present disclosure, a gap is provided between the source and the drain, the insulation dielectric layer includes a first top surface facing the gap and a first bottom surface away from the gap, and a distance between the first top surface and the first bottom surface is d; the channel includes a second top surface facing the source and/or the drain and a second bottom surface away from the source and/or the drain, and a distance between the second top surface and the second bottom surface is D; where d is less than D.

In some embodiments of the present disclosure, d=( 1/10 to ½)×D.

In some embodiments of the present disclosure, d=( 1/10 to ⅓)×D.

In some embodiments of the present disclosure, in a cross-section of the thin film transistor in the first direction, the source and the drain are located on two sides of the insulation layer in the second direction; the insulation dielectric layer partially overlaps with the source and/or the drain; and the second direction is perpendicular to the first direction.

In some embodiments of the present disclosure, a projection of the insulation dielectric layer on the substrate and a projection of the source and/or the drain on the substrate have an overlapping region.

In some embodiments of the present disclosure, a material of the insulation dielectric layer includes any one of aluminum oxide, silicon oxide, silicon oxynitride, tantalum oxide, hafnium oxide, silicon nitride, tantalum oxide, or zirconium oxide; or a stack formed by two or more of aluminum oxide, silicon oxide, silicon oxynitride, tantalum oxide, hafnium oxide, silicon nitride, tantalum oxide, and zirconium oxide.

In some embodiments of the present disclosure, a material of the channel includes any one of ZnO, InO, TiO, IGZO, IAZO, ITZO, or ITO.

Another aspect of the present disclosure provides a memory, including memory cells, where each memory cell includes a capacitor and the thin film transistor as described in the first aspect.

In some embodiments of the present disclosure, the memory includes a dynamic random access memory.

Another aspect of the present disclosure provides a method of manufacturing a thin film transistor. The method includes: providing a substrate; sequentially stacking, in a first direction, a gate and an insulation layer on a surface of the substrate, so that the insulation layer covers the gate; and sequentially forming a channel, an insulation dielectric layer, and a source and a drain on a surface of the insulation layer away from the gate; where the insulation dielectric layer is located between the source and the drain, and the insulation dielectric layer partially overlaps with the channel in the first direction.

In some embodiments, forming the channel and the insulation dielectric layer includes: forming a first channel layer on the surface of the insulation layer away from the gate; forming the insulation dielectric layer at a middle position of a surface of the first channel layer away from the insulation layer; and forming a second channel layer on two sides of the insulation dielectric layer in the second direction.

In some embodiments, forming the channel and the insulation dielectric layer includes: forming the channel on the surface of the insulation layer away from the gate; forming a trench at a middle position of a surface of the channel away from the insulation layer; and forming the insulation dielectric layer in the trench.

### BRIEF DESCRIPTION OF THE DRAWINGS

Through reading detailed description of preferred embodiments below, various other advantages and benefits will become clearer to those skilled in the art. The accompanying drawings are only for purpose of illustrating the preferred embodiments and are not to be construed as limitations on the present disclosure. Furthermore, throughout the drawings, the same reference numbers are used to represent the same components. In the accompanying drawings:

FIG. 1 schematically shows a circuit diagram of a memory cell according to some embodiments of the present disclosure.

FIG. 2 schematically shows a schematic structural diagram of a thin film transistor according to some embodiments of the present disclosure.

FIG. 3 schematically shows another schematic structural diagram of a thin film transistor according to some embodiments of the present disclosure.

FIG. 4 schematically shows another schematic structural diagram of a thin film transistor according to some embodiments of the present disclosure.

FIG. 5 schematically shows another schematic structural diagram of a thin film transistor according to some embodiments of the present disclosure.

FIG. 6 schematically shows another schematic structural diagram of a thin film transistor according to some embodiments of the present disclosure.

FIG. 7 schematically shows another schematic structural diagram of a thin film transistor according to some embodiments of the present disclosure.

FIG. 8 schematically shows a schematic diagram of steps in a process of manufacturing a thin film transistor according to some embodiments of the present disclosure.

FIG. 9 to FIG. 18 schematically show schematic diagrams of structures obtained at various steps in a process of manufacturing the thin film transistor shown in FIG. 7, where:

FIG. 11A and FIG. 11B are schematic diagrams of a structure in different directions, and FIG. 11B is a top view;

FIG. 14A and FIG. 14B are schematic diagrams of a structure in different directions, and FIG. 14B is a top view in a manufacturing process; and

FIG. 15A and FIG. 15B are schematic diagrams of a structure in different directions, and FIG. 15B is a top view in a manufacturing process.

### DETAILED DESCRIPTION OF EMBODIMENTS

In order to make purpose, technical solution and advantages of the present disclosure clearer, further descriptions are provided below in conjunction with accompanying drawings and specific embodiments. It should be understood that the specific embodiments described here are only used to describe the present disclosure and are not intended to limit the present disclosure. Based on embodiments in the present disclosure, all other embodiments obtained by those of ordinary skill in the art without creative effort fall within scope of protection of the present disclosure.

Various schematic structural diagrams according to embodiments of the present disclosure are shown in the accompanying drawings. These drawings are not drawn to scale, and for the purpose of clarity, some details have been enlarged, and some details have been omitted. Shapes of various regions and layers shown in the drawings, as well as their relative sizes and positional relationships are only exemplary. In practice, there may be deviations due to manufacturing tolerances or technical limitations, and those skilled in the art may additionally design regions/layers with different shapes, sizes, and relative positions as desired in practice.

In the context of the present disclosure, when a layer/component is referred to as being “on” a further layer/element, the layer/element may be directly on the further layer/element, or there may be a middle layer/element between them. In addition, if a layer/element is located “on” the further layer/element in an orientation, when the orientation is reversed, the layer/element may be located “below” the further layer/element.

The present disclosure may use the term “coupled with” along with its derivatives. “Coupled” may refer to one or more of the following. “Coupled” may refer to that two or more elements are in direct physical or electrical contact; “coupled” may also refer to that two or more elements are in indirect contact with each other, but still collaborate or interact with each other, and one or more other elements are coupled or connected between the elements coupled with each other. The term “directly coupled” may refer to that two or more elements are in direct contact.

DRAM is a volatile, capacitor-based, destructive read form of semiconductor memory that currently accounts for more than 50% of the memory market. DRAM includes memory cells, and each memory cell includes a transistor and a capacitor. The memory cells are arranged in a two-dimensional matrix. The basic operation mechanism includes reading mechanism (Read) and writing mechanism (Write). When reading, the bit line (BL) is charged to be at half of an operating voltage, and then the transistor is turned on, so that charges are shared by the BL and the capacitor. If an internally stored value is 1, a voltage of the BL is raised to be greater than half of the operating voltage through charge sharing. Conversely, if the internally stored value is 0, the voltage of the BL is pulled down to be less than half of the operating voltage. After obtaining the voltage of the BL, an amplifier is used to determine whether the internal value is 0 or 1. When writing, the transistor is turned on, if writing 1, the voltage of the BL is raised to the operating voltage, so that the capacitor stores the operating voltage; if writing 0, the voltage of the BL is reduced to 0 volts, so that no charge is stored in the capacitor.

TFT is a field-effect transistor that includes a channel layer, a gate, and a source and a drain on a supporting but non-conductive substrate. Due to advantages such as low leakage current, low growth temperature and high mobility, the thin film transistor has been widely used in various devices, such as memory.

Existing thin film transistors or memories still face technical challenges such as increased leakage current and increased energy consumption.

The present disclosure provides a thin film transistor, a memory and a method of manufacturing a thin film transistor. The thin film transistor includes an insulation dielectric layer provided between the source and the drain, the insulation dielectric layer partially overlaps with the channel in a first direction. Compared to providing a passivation layer on the channel in an existing structure, the insulation dielectric layer provided in the present disclosure effectively reduces the mobility of most electrons when the device is turned off, thereby significantly reducing leakage current.

The present disclosure provides a thin film transistor. The thin film transistor includes a substrate, a gate, an insulation layer, a channel, a source and a drain, and an insulation dielectric layer stacked in the first direction. The gate is provided on any surface of the substrate, the insulation layer is provided on the gate, and the insulation layer covers the gate. The channel is provided between the insulation layer and the source and the drain. The source and the drain are located on a surface of the channel away from the substrate. The insulation dielectric layer is provided between the source and the drain. In the first direction, the insulation dielectric layer partially overlaps with the channel.

The “first direction” in the present disclosure refers to a stacking direction of the thin film transistor, and may also refer to a thickness direction of the thin film transistor, and may also refer to the Z direction in the drawings.

The “partially overlap” in the present disclosure includes fully overlap or partially overlap in the first direction. The overlap in embodiments of the present disclosure does not refer to direct physical overlap, but refers to a projection of the insulation dielectric layer on the channel being located in the channel.

The “leakage current” in the present disclosure refers to a small current that exists between the source and the drain of the device when the device is turned off. The leakage current is caused by the structure and material properties of the device.

In the present disclosure, through providing the insulation dielectric layer between the source and the drain which partially overlaps with the channel in the first direction, the mobility of most electrons is effectively reduced when the device is turned off, and the leakage current and the power consumption are significantly reduced, compared to providing a passivation layer on the channel in an existing structure.

The memory cell in the present disclosure includes the thin film transistor and the capacitor. Multiple memory cells are arranged in an array to form a memory. Multiple memories are arranged in an array to form a memory array. The memory array is coupled to a circuit board to form a computing device with the circuit board.

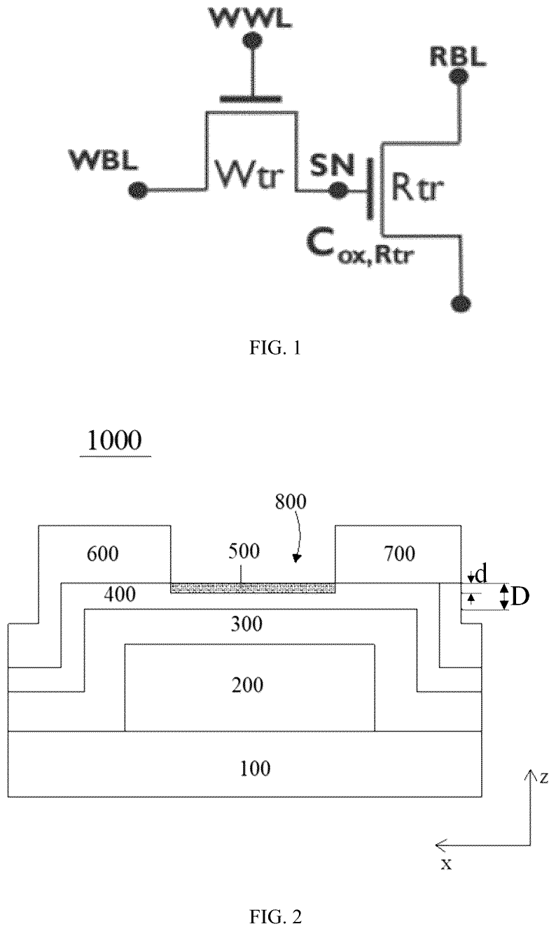

The thin film transistor in the present disclosure may be used to form a capacitor-free 2T0C DRAM, a circuit diagram of the memory cell including the thin film transistor is shown in FIG. 1. One transistor serves as a writing transistor, and the other transistor serves as a reading transistor. The capacitor may be stored in the reading transistor, and reading and writing are controlled only by the transistor, so as to reduce power consumption of the device.

In some embodiments of the present disclosure, a gap is provided between the source of the thin film transistor and the drain of the thin film transistor. The insulation dielectric layer includes a first top surface facing the gap. The channel includes a second top surface facing the source and/or the drain. The first top surface is flush with the second top surface. In the embodiments, in the first direction, the insulation dielectric layer fully overlaps with the channel, and the insulation dielectric layer is well “embedded” in the channel. The structure of the thin film transistor is shown in FIG. 2.

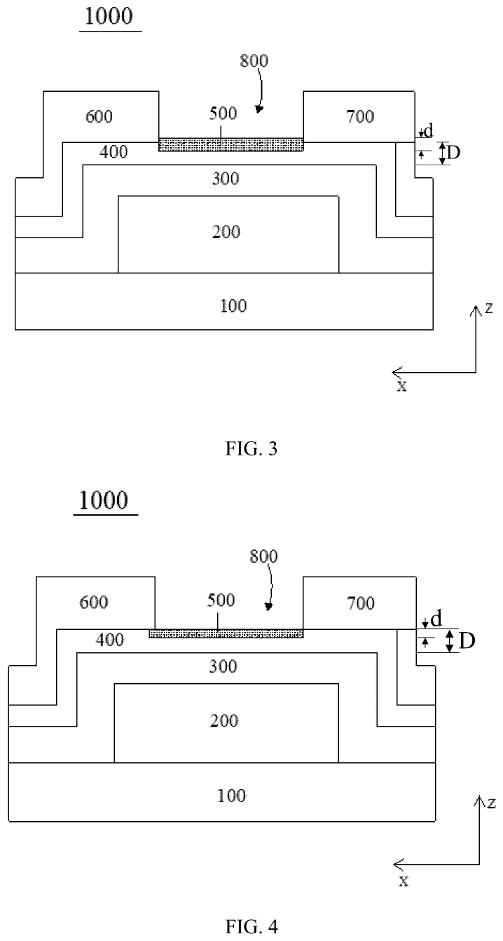

In some embodiments of the present disclosure, a gap is provided between the source and the drain. The insulation dielectric layer includes a first top surface facing the gap. The channel includes a second top surface facing the source and/or the drain. The first top surface is higher than the second top surface. In the embodiments, in the first direction, the insulation dielectric layer partially overlaps with the channel, and the structure of the thin film transistor is shown in FIG. 3.

In the present disclosure, no matter whether the thin film transistor shown in FIG. 2 or FIG. 3 is adopted, a charge concentration flowing in the channel when the device is turned off is reduced.

In some embodiments of the present disclosure, a thickness of the insulation dielectric layer in the first direction is described. With reference to FIG. 2 and FIG. 3, a gap 800 is provided between the source and the drain. The insulation dielectric layer includes a first top surface facing the gap and a first bottom surface away from the gap. A distance between the first top surface and the first bottom surface is the thickness of the insulation dielectric layer, which is represented by a mathematical symbol d. Similarly, the channel includes a second top surface facing the source and/or the drain and a second bottom surface away from the source and/or the drain. A distance between the second top surface and the second bottom surface is D. In practical manufacturing, d<D is satisfied, which facilitates manufacturing while effectively reducing leakage current of the device.

In some embodiments of the present disclosure, there is further provided a mathematical equation that is met between the thickness d of the insulation dielectric layer and the thickness D of the channel: d=( 1/10 to ½)×D.

In some embodiments of the present disclosure, there is further defined that d=( 1/10 to ⅓)×D. In these embodiments, the first top surface is flush with the second top surface.

In addition to describing the thickness of the insulation dielectric layer in the first direction, in some embodiments of the present disclosure, there is also described that in a second direction perpendicular to the first direction, the insulation dielectric layer partially overlaps with the source and/or the drain. The second direction may refer to a length direction of the thin film transistor or a width direction of the thin film transistor, which may also refer to the X direction in the drawings.

In these embodiments, the “overlap” here does not refer to direct physical overlap, but rather refers to that a projection of the insulation dielectric layer on the substrate and a projection of the source and/or the drain on the substrate have an overlapping region.

As shown in FIG. 4, the insulation dielectric layer partially overlaps with the source in the second direction, that is, the projection of the insulation dielectric layer on the substrate and the projection of the source on the substrate have an overlapping region.

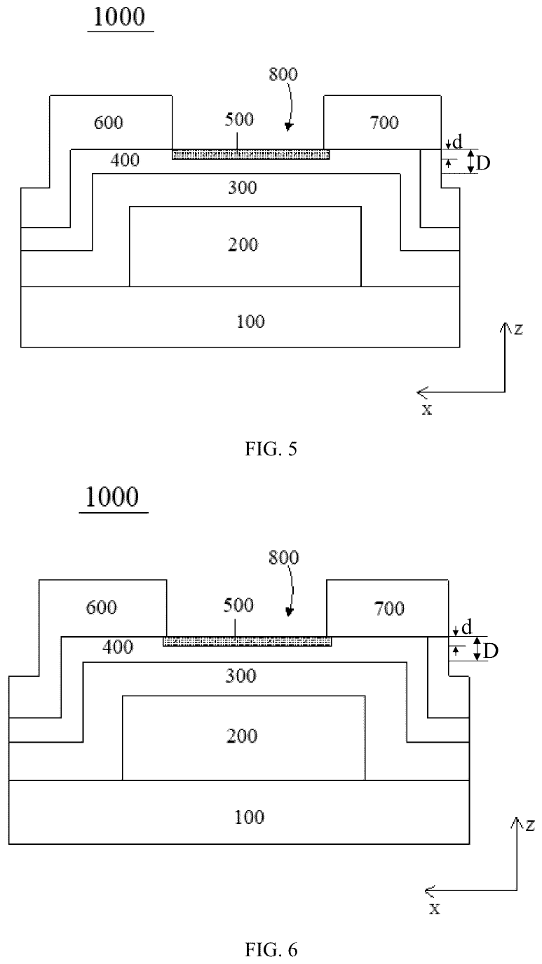

As shown in FIG. 5, the insulation dielectric layer partially overlaps with the drain in the second direction, that is, the projection of the insulation dielectric layer on the substrate and the projection of the drain on the substrate have an overlapping region.

As shown in FIG. 6, the insulation dielectric layer partially overlaps with the source and the drain in the second direction, that is, the projection of the insulation dielectric layer on the substrate and the projections of the source and the drain on the substrate have overlapping regions.

In embodiments of the present disclosure, any of the structures shown in FIG. 4 to FIG. 6 may be used to improve the insulation effect between the source and the drain, thereby effectively reducing the mobility of most electrons when the device is turned off.

In some embodiments of the present disclosure, a material of the channel includes, but is not limited to, amorphous semiconductor material and/or polycrystalline semiconductor material formed by any one of ZnO (zinc oxide), InO (indium oxide), TiO (titanium oxide), IGZO (indium gallium zinc oxide), IAZO (indium aluminum zinc oxide), ITZO (indium tin zinc oxide), or ITO (indium tin oxide). In some embodiments of the present disclosure, the material of the channel is an amorphous semiconductor material of IGZO (indium gallium zinc oxide).

In some embodiments of the present disclosure, the material of the insulation dielectric layer includes, but is not limited to, any one of aluminum oxide, silicon oxide, silicon oxynitride, tantalum oxide, hafnium oxide, silicon nitride, tantalum oxide, or zirconium oxide; or a stack formed by two or more of aluminum oxide, silicon oxide, silicon oxynitride, tantalum oxide, hafnium oxide, silicon nitride, tantalum oxide, and zirconium oxide. In some embodiments of the present disclosure, the insulation dielectric layer includes a stack formed by silicon oxide and silicon nitride.

In some embodiments of the present disclosure, the material of each of the gate, the source and the drain includes, but is not limited to, aluminum (Al), platinum (Pt), gold (Au), tungsten (W), titanium (Ti), cobalt (Co), TiN (titanium nitride), Ti (titanium), In—Ti—O (ITO, indium tin oxide), or any combination thereof.

In some embodiments, the present disclosure provides an insulation layer, which may serve as a gate dielectric layer. A material of the insulation layer includes a material with a certain dielectric constant, such as hafnium dioxide.

In some embodiments of the present disclosure, the material of the substrate includes one or more semiconductor materials. Non-limiting examples of suitable materials of the substrate include Si (silicon), strained Si, carbon-doped silicon, Ge (germanium), SiGe (silicon germanium), carbon-doped silicon germanium, Si alloy, Ge alloy, III-V semiconductor materials (such as GaAs (gallium arsenide), InAs (indium arsenide), InP (indium phosphide), or indium gallium arsenide (InGaAs), or any combination thereof. In these embodiments, the substrate may be a silicon substrate, including but not limited to silicon, single crystal silicon, polycrystalline silicon, amorphous silicon, silicon-on-nothing (SON), silicon-on-insulator (SOI), or silicon-on-replacement insulator (SRI), or a silicon germanium substrate, and the like. Additionally or alternatively, the substrate may include various insulation, doping, and/or device features.

In some embodiments of the present disclosure, a buffer layer may be provided between the substrate and the gate. The buffer layer may include any one or more of silicon oxide (SiOx), silicon nitride (SiNx), and silicon oxynitride (SiON), and may be a single layer, multiple layers, or composite layers. Although the present disclosure does not directly illustrate the buffer layer in the drawings, the buffer layer actually exists.

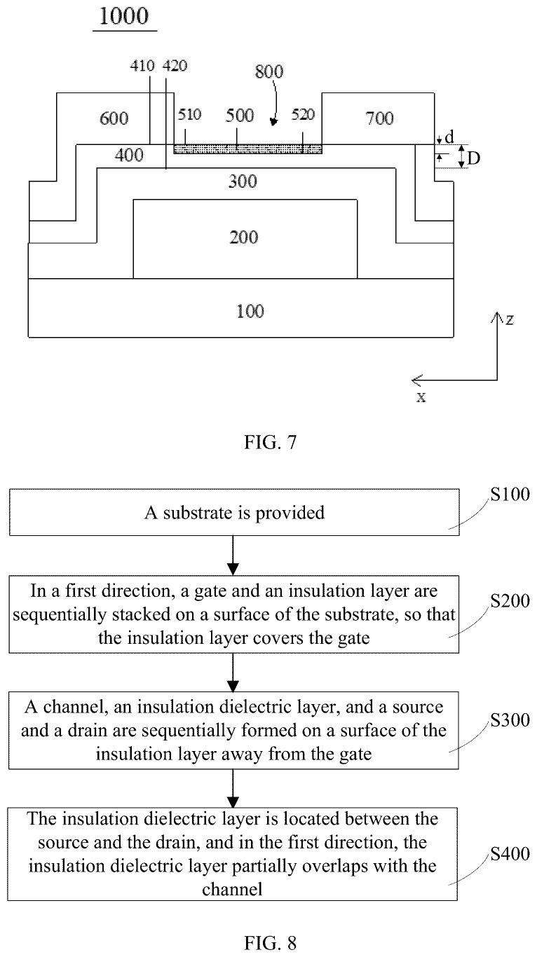

In order to better describe the structure of the thin film transistor in the present disclosure, a detailed description will be provided with reference to FIG. 7. In some embodiments of the present disclosure, as shown in FIG. 7, a thin film transistor 1000 with a specific structure includes a substrate 100, a gate 200, an insulation layer 300, a channel 400, an insulation dielectric layer 500, a source 600 and a drain 700 sequentially stacked from bottom to top. The gate 200 is a patterned gate. The insulation layer 300 fully covers the gate 200. The insulation layer 300 is a patterned insulation layer. In the cross-section of the thin film transistor in the first direction, the heights of the parts of the insulation layer 300 on two sides of the insulation layer 300 in the second direction are significantly lower than a height of the middle part of the insulation layer 300. The channel 400 is provided between the insulation layer 300 and the source 600 and the drain 700. The source 600 and the drain 700 are located on a surface of the channel away from the substrate, and in the cross-section of the thin film transistor in the first direction, the source and the drain are located on two sides of the insulation layer in the second direction.

With reference to FIG. 7, a gap 800 is provided between the source 600 and the drain 700. The insulation dielectric layer 500 is provided below the gap 800. The insulation dielectric layer 500 includes a first top surface 510 facing the gap 800 and a first bottom surface 520 away from the gap 800. A distance between the first top surface and the first bottom surface is d. The channel 400 includes a second top surface 410 facing the source and/or the drain and a second bottom surface 420 away from the source and/or the drain. A distance between the second top surface and the second bottom surface is D. As shown in FIG. 7, the first top surface is flush with the second top surface, and the distance d between the first top surface and the first bottom surface is less than the distance D between the second top surface and the second bottom surface, so as to “embed” the insulation dielectric layer into the top of the channel. Even if the device is turned off, there are still some electrons flowing at the top of the channel located between the drain and the source, and an electron concentration at the top of the channel located between the drain and the source is higher than electron concentrations at other positions, which is the main source of leakage current. In the present disclosure, by providing an insulation dielectric layer at the top of the channel located between the drain and the source, a flowing path of electrons is effectively blocked and the electron concentration is reduced, thereby reducing leakage current. The “embedding” method in the present disclosure is different from directly providing a passivation layer on a surface of the channel layer. Although the passivation layer may reduce leakage current to a certain extent, it cannot effectively reduce the electron concentration at the top of the channel between the source and the drain, so that the improvement effect thereof is limited.

The thin film transistor 1000 shown in FIG. 7 of the present disclosure is a planar semiconductor device. The thin film transistor may be doped with N-type impurities by using any existing methods in the field to form an N-type transistor, or doped with P-type impurities by using any existing methods in the field to form a P-type transistor.

Another aspect of the present disclosure provides a method of manufacturing a thin film transistor. The flow chart of the manufacturing method is shown in FIG. 8, and the method includes steps S100 to S400.

In step S100, a substrate is provided.

In step S200, a gate and an insulation layer are sequentially stacked, in a first direction, on a surface of the substrate, so that the insulation layer covers the gate.

In step S300, a channel, an insulation dielectric layer, and a source and a drain are sequentially formed on a surface of the insulation layer away from the gate.

In step S400, the insulation dielectric layer is located between the source and the drain, and in the first direction, the insulation dielectric layer partially overlaps with the channel.

In some embodiments of the present disclosure, the channel and the insulation dielectric layer are obtained by: forming a first channel layer on the surface of the insulation layer away from the gate; forming the insulation dielectric layer at a middle position of a surface of the first channel layer away from the insulation layer; and forming a second channel layer on two sides of the insulation dielectric layer in the second direction.

In some embodiments of the present disclosure, the channel and the insulation dielectric layer are obtained by: forming the channel on the surface of the insulation layer away from the gate; forming a trench at a middle position of a surface of the channel away from the insulation layer; and forming the insulation dielectric layer in the trench.

In some embodiments of the present disclosure, the method of depositing each layer includes but is not limited to physical deposition and/or chemical deposition.

In order to better describe the structure of the thin film transistor in the present disclosure, the thin film transistor shown in FIG. 7 will be described in detail below with reference to FIG. 9 to FIG. 18.

As shown in FIG. 9, a substrate is provided, and the material of the substrate may be described as above.

As shown in FIG. 10, a gate is formed by depositing on a surface of the substrate. The material of the gate may be described as above. The deposition method includes but is not limited to PVD (Physical Vapor Deposition), CVD (Chemical Vapor Deposition), PECVD (Plasma-Enhanced Chemical Vapor Deposition), Inductively Coupled Plasma Chemical Vapor Deposition (ICP CVD), or any combination thereof.

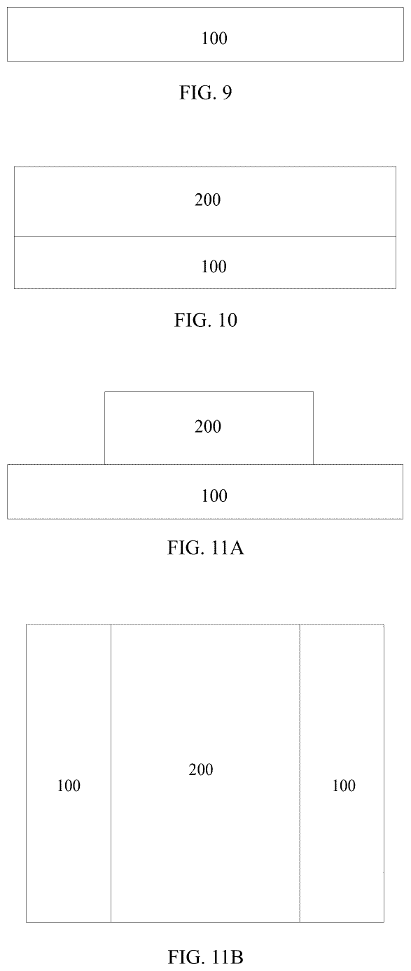

As shown in FIG. 11A and FIG. 11B, patterning is performed on the gate. The patterning etching process includes any existing form in this field, including specific process flows such as exposure, development, and etching.

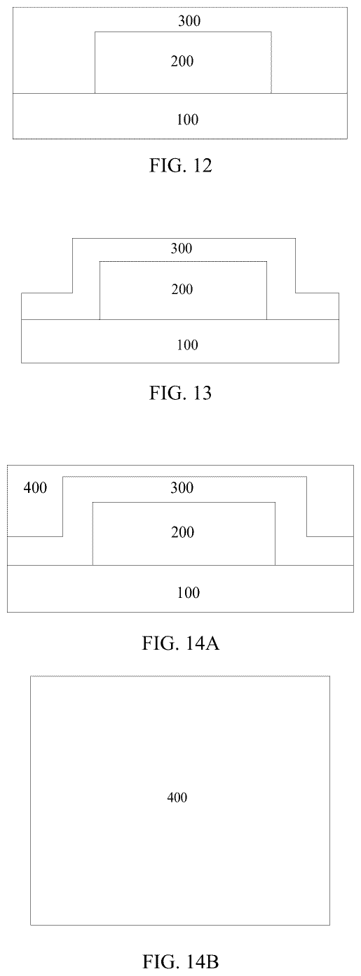

As shown in FIG. 12 and FIG. 13, an insulation layer is formed by depositing on the surface of the patterned gate, so that the insulation layer covers the patterned gate. In the second direction, patterning is performed on parts of the insulation layer on two sides of the first direction, so that heights of the parts of the insulation layer on two sides are lower than a height of the middle part of the insulation layer.

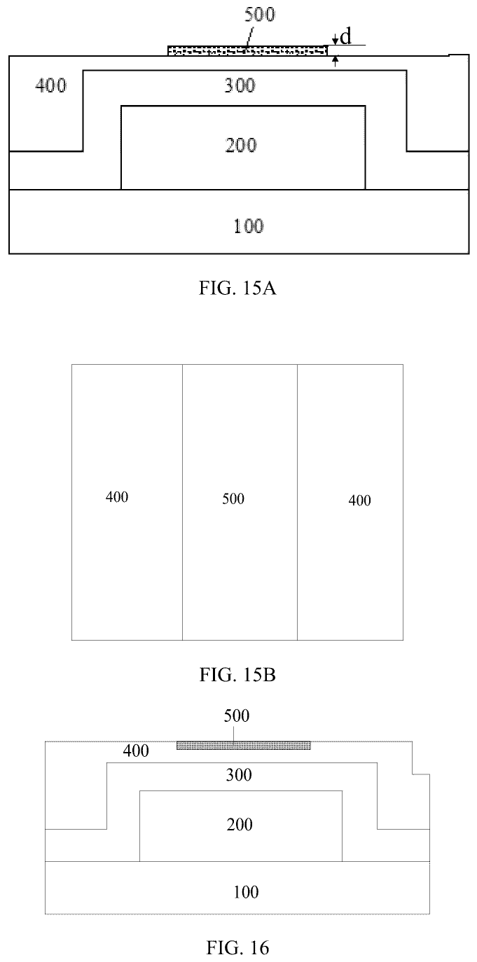

As shown in FIG. 14A and FIG. 14B, a part of the channel is formed by depositing on the surface of the patterned insulation layer, which may be a first channel layer. The formation method of the channel includes but is not limited to epitaxial growth, sputtering, etc. The channel may be formed by using a gas source of the channel material together with a carrier gas.

As shown in FIG. 15A and FIG. 15B, an insulation dielectric layer is formed by depositing at a middle position of the first channel layer. The deposition method includes but is not limited to PECVD (Plasma-Enhanced Chemical Vapor Deposition), etc.

As shown in FIG. 16, a remaining part of channel is formed by depositing on two sides of the insulation dielectric layer in the second direction, which may be a second channel layer. The first channel layer and the second channel layer together form an entire channel. A projection of the insulation dielectric layer on the channel is completely located in the channel, so that the insulation dielectric layer is “embedded” in the top of the channel.

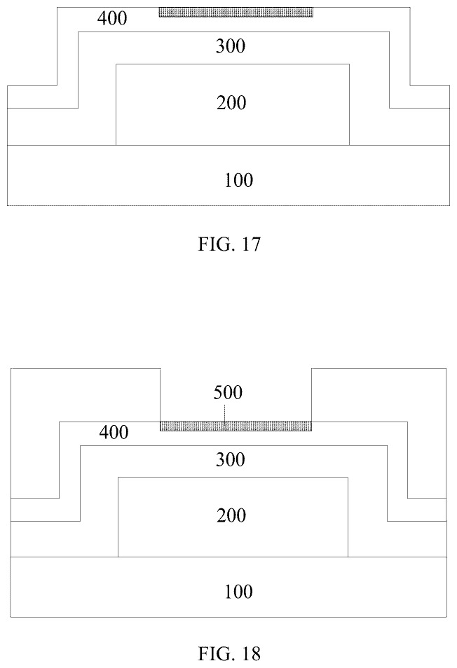

As shown in FIG. 17, in the second direction, patterning is performed on the channel on two sides of the first direction.

As shown in FIG. 18, in the second direction, the source and the drain are formed by depositing on the surface of the channel on two sides of the first direction respectively.

The formed source and drain are patterned to obtain the thin film transistor shown in FIG. 7.

In the above manufacturing process, the present disclosure provides a detailed description of one of the methods of manufacturing a thin film transistor, with reference to the accompanying drawings. In addition, the present disclosure further includes other methods, such as the above method of forming a trench by etching the channel. The present disclosure does not elaborate further on this manufacturing process.

In summary, the thin film transistor and the device provided in the present disclosure may effectively reduce the mobility of most electrons when the device is turned off, thereby significantly reducing leakage current and power consumption.

It should be understood that the terms used in the text are only for the purpose of describing specific exemplary embodiments and are not intended to be limiting. Unless otherwise explicitly stated in the context, singular forms such as “one”, “a” “an”, and “the” used in the text may also refer to plural forms. The terms “including”, “comprising”, “containing”, and “having” are inclusive and thus indicate the presence of the stated features, steps, operations, elements, and/or components, but do not exclude the presence or addition of one or more other features, steps, operations, elements, components, and/or combinations thereof. The method steps, processes, and operations described in the text are not to be interpreted as necessarily requiring them to be performed in the specific order described or explained, unless the performing order is explicitly stated. It should also be understood that additional or alternative steps may be used. The above description is only preferred embodiments of the present disclosure, but the scope of protection of the present disclosure is not limited thereto. Any variations or substitutions that may be easily conceived by those skilled in the art within the technical scope disclosed in the present disclosure should be included within the scope of protection of the present disclosure. Therefore, the scope of protection of the present disclosure shall be subject to the scope of protection of the claims.

What is claimed is:

1. A thin film transistor, comprising:
a substrate;
a gate on a surface of the substrate;
an insulation layer covering the gate;
a source and a drain;
a channel between the insulation layer and the source and the drain, wherein the source and the drain are located on a surface of the channel away from the substrate; and
an insulation dielectric layer between the source and the drain, wherein the insulation dielectric layer partially overlaps with the channel in a first direction,
wherein the substrate, the gate, the insulation layer, the source and the drain, the channel, and the insulation dielectric layer are stacked in the first direction.

2. The thin film transistor of claim 1, wherein a gap is provided between the source and the drain, the insulation dielectric layer comprises a first top surface facing the gap, and the channel comprises a second top surface facing the source and/or the drain; and
wherein the first top surface is flush with the second top surface.

3. The thin film transistor of claim 1, wherein a gap is provided between the source and the drain, the insulation dielectric layer comprises a first top surface facing the gap, and the channel comprises a second top surface facing the source and/or the drain, and
wherein the first top surface is higher than the second top surface.

4. The thin film transistor of claim 1, wherein a gap is provided between the source and the drain, the insulation dielectric layer comprises a first top surface facing the gap and a first bottom surface away from the gap, and a distance between the first top surface and the first bottom surface is d;
wherein the channel comprises a second top surface facing the source and/or the drain and a second bottom surface away from the source and/or the drain, and a distance between the second top surface and the second bottom surface is D; and
wherein d is less than D.

5. The thin film transistor of claim 2, wherein the insulation dielectric layer further comprises a first bottom surface away from the gap, and a distance between the first top surface and the first bottom surface is d;
wherein the channel further comprises a second bottom surface away from the source and/or the drain, and a distance between the second top surface and the second bottom surface is D; and
wherein d is less than D.

6. The thin film transistor of claim 5, wherein d=( 1/10 to ½)×D.

7. The thin film transistor of claim 5, wherein d=( 1/10 to ⅓)×D.

8. The thin film transistor of claim 3, wherein the insulation dielectric layer further comprises a first bottom surface away from the gap, and a distance between the first top surface and the first bottom surface is d;
wherein the channel further comprises a second bottom surface away from the source and/or the drain, and a distance between the second top surface and the second bottom surface is D; and
wherein d is less than D.

9. The thin film transistor of claim 8, wherein d=( 1/10 to ½)×D.

10. The thin film transistor of claim 8, wherein d=( 1/10 to ⅓)×D.

11. The thin film transistor of claim 1, wherein in a cross-section of the thin film transistor in the first direction, the source and the drain are located on two sides of the insulation layer in a second direction; and
the second direction is perpendicular to the first direction.

12. The thin film transistor of claim 2, wherein in a cross-section of the thin film transistor in the first direction, the source and the drain are located on two sides of the insulation layer in a second direction; and
the second direction is perpendicular to the first direction.

13. The thin film transistor of claim 11, wherein a projection of the insulation dielectric layer on the substrate and a projection of the source and/or the drain on the substrate have an overlapping region.

14. The thin film transistor of claim 1, wherein a material of the insulation dielectric layer comprises any one of aluminum oxide, silicon oxide, silicon oxynitride, tantalum oxide, hafnium oxide, silicon nitride, tantalum oxide, or zirconium oxide; or a stack formed by two or more of aluminum oxide, silicon oxide, silicon oxynitride, tantalum oxide, hafnium oxide, silicon nitride, tantalum oxide, and zirconium oxide.

15. The thin film transistor of claim 14, wherein a material of the channel comprises any one of ZnO, InO, TiO, IGZO, IAZO, ITZO, or ITO.

16. A memory comprising memory cells, wherein each memory cell comprises a capacitor and the thin film transistor of claim 1.

17. The memory of claim 16, wherein the memory comprises a dynamic random access memory.

18. A method of manufacturing a thin film transistor, comprising:
providing a substrate;
sequentially stacking, in a first direction, a gate and an insulation layer on a surface of the substrate, so that the insulation layer covers the gate; and
sequentially forming a channel, an insulation dielectric layer, and a source and a drain on a surface of the insulation layer away from the gate,
wherein the insulation dielectric layer is located between the source and the drain, and the insulation dielectric layer partially overlaps with the channel in the first direction.

19. The method of claim 18, wherein forming the channel and the insulation dielectric layer comprises:
forming a first channel layer on the surface of the insulation layer away from the gate;
forming the insulation dielectric layer at a middle position of a surface of the first channel layer away from the insulation layer; and
forming a second channel layer on two sides of the insulation dielectric layer in a second direction perpendicular to the first direction.

20. The method of claim 18, wherein forming the channel and the insulation dielectric layer comprises:
forming the channel on the surface of the insulation layer away from the gate;
forming a trench at a middle position of a surface of the channel away from the insulation layer; and
forming the insulation dielectric layer in the trench.
